(19) United States
(12) Patent Application Publication
(10) Pub. No.: US 2012/0105121 A1
(43) Pub. Date: May 3, 2012

(54) Device and Method for Signal Amplification

(76) Inventor: Ming-Hung Chang, Hsinchu County (TW)

(21) Appl. No.: 13/026,284

(22) Filed: Feb. 13, 2011

(30) Foreign Application Priority Data
Oct. 29, 2010 (TW) 099137294

(51) Int. Cl. H03K 3/01

(52) U.S. Cl. 327/172

(57) ABSTRACT

A signal amplification device for amplifying a signal according to a gain indication signal is disclosed. The signal amplification device includes a pulse width modulator for generating a pulse width modulation signal according to the gain indication signal, a counter for counting a period number of the pulse width modulation signal according to a standard clock signal, and an amplifier for amplifying the signal according to the period number.

### BACKGROUND OF THE INVENTION

1. Field of the Invention

The present invention is related to a signal amplification device and method, and more particularly, to a signal amplification device and method which replace analog-to-digital conversion by pulse width measurement.

2. Description of the Prior Art

With advances in integrated circuit manufacturing, an analog-to-digital converter (ADC) is allowed to output a digital signal composed of more bits. In such a situation, a value represented by the digital signal can more precisely approach an analog signal received by the ADC. To do so, the ADC requires more circuit layout area, complexity and robustness against noise. If the noise rejection ability is not sufficient, signal distortion happens during the analog-to-digital conversion, which offsets advantages of the additional bits of the digital number.

For example, please refer to FIG. 1, which is a schematic diagram of a signal amplification device 10 of the prior art. The signal amplification device 10 amplifies a signal V1 based on a gain indication signal G_IND, and includes a pulse width modulator 100, a lowpass filter 102, an ADC 104 and an amplifier 106. The pulse width modulator 100 generates a pulse width modulation (PWM) signal VPWM with a duty cycle directly proportional to a gain indicated by the gain indication signal G_IND. The lowpass filter 102 performs lowpass filtering on the PWM signal VPWM to generate an average voltage VAVG of the PWM signal VPWM. The ADC 104 converts the average voltage VAVG into an N-bit digital signal DGT. Finally, the amplifier 110 amplifies the signal V1 according to the gain indicated by the digital signal DGT to output an amplified signal V1′.

Please continue to refer to FIG. 2, which is a schematic diagram of a conversion relationship between the average voltage VAVG and the digital signal DGT. In general, a voltage range of the average voltage VAVG is between a power voltage VDD and a ground voltage VGND. If the power voltage is 5V, the ground voltage is 0V and N=6, every stage of the digital signal DGT corresponds to (5−0)/2⁶=78 mV of the voltage range of the average voltage VAVG. That is, the ADC 104 utilizes 78 mV as a unit to convert the average voltage VAVG into the digital signal DGT. If the power voltage VDD decreases from 5V to 2.5V or the bit number N increases from six to seven, the conversion unit of the ADC 104 further decreases to 39 mV. In other words, if the power voltage VDD decreases or the bit number N increases, the ADC 104 requires higher conversion accuracy.

However, since the ADC 104 and amplifier 106 generally have to share pins receiving the power voltage VDD and the ground voltage VGND due to limited pin number, the power voltage VDD and the ground voltage VGND tend to vibrate when the amplifier 106 outputs high power. In such a situation, stages of the digital signal DGT vibrate with the power voltage VDD and the ground voltage VGND, as illustrated in FIG. 3. In FIG. 3, the average voltage VAVG is converted into the digital signal DGT as “000100”, “000011”, “000100” in sequence. When the conversion unit is compressed due to the increasing bit number N, probability of erroneous conversion increases, resulting in an unstable gain and an unstable amplified signal V1′ of the amplification device 10. In a worse case, since the ADC 104 and the amplifier 106 share the same power reception pins, parasitic resistors existing on the shared power reception routes deteriorate the offsets of the power voltage VDD and the ground voltage VGND and enlarge variation of the N-bit digital signal DGT.

Therefore, economically stabilization of the gain of the signal amplification device is a major focus of the industry.

### SUMMARY OF THE INVENTION

It is therefore a primary objective of the claimed invention to provide a signal amplification device and a signal amplification method.

The present invention discloses a signal amplification device for amplifying a signal according to a gain indication signal. The signal amplification device comprises a pulse width modulator for generating a pulse width modulation (PWM) signal according to the gain indication signal, a counter for counting a width cycle number of the PWM signal according to a standard clock signal, and an amplifier for amplifying the signal according to the cycle number to generate an amplified signal.

The present invention further discloses a signal amplification method for amplifying a signal according to a gain indication signal. The signal amplification method comprises generating a pulse width modulation (PWM) signal according to the gain indication signal, counting a width cycle number of the PWM signal according to a standard clock signal, and amplifying the signal according to the cycle number to generate an amplified signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a signal amplification device of the prior art.

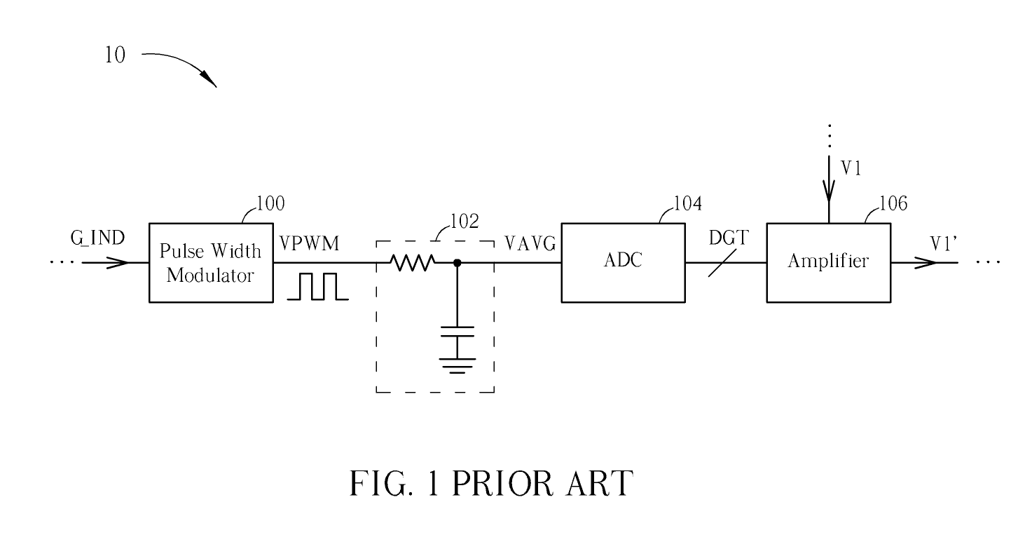

FIG. 2 is a schematic diagram of conversion relationship between an average voltage and a digital signal of the signal amplification device shown in FIG. 1.

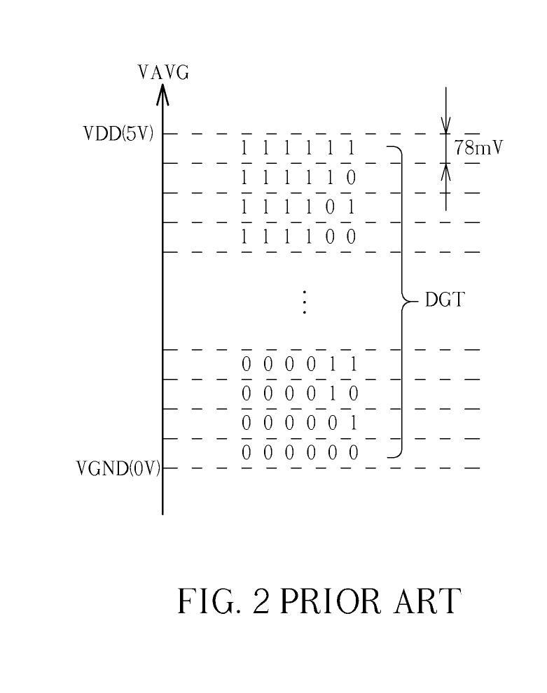

FIG. 3 is a timing diagram of stages of the digital signal of the signal amplification device shown in FIG. 1.

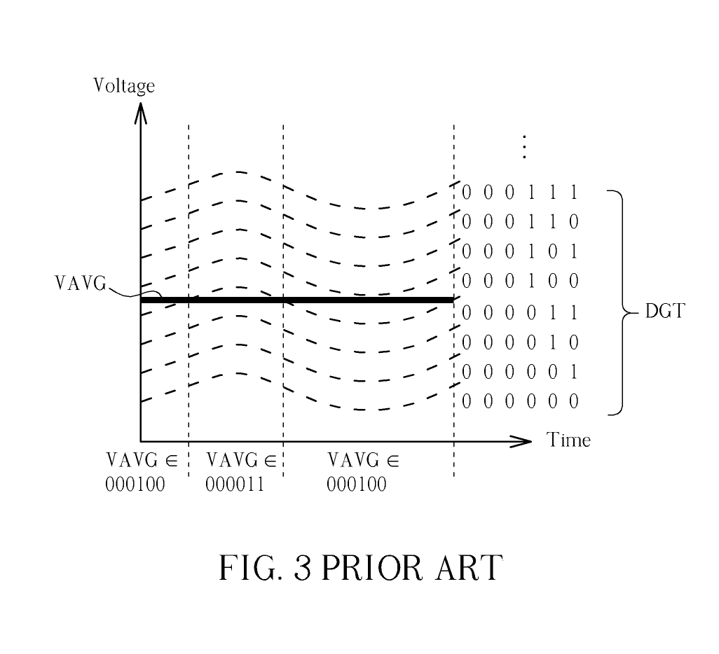

FIG. 4 is a schematic diagram of a signal amplification device according to an embodiment of the present invention.

FIG. 5 is a timing diagram of a pulse width modulation signal and a standard clock signal of the signal amplification device shown in FIG. 4.

FIG. 6 is a signal amplification process according to an embodiment of the present invention.

### DETAILED DESCRIPTION

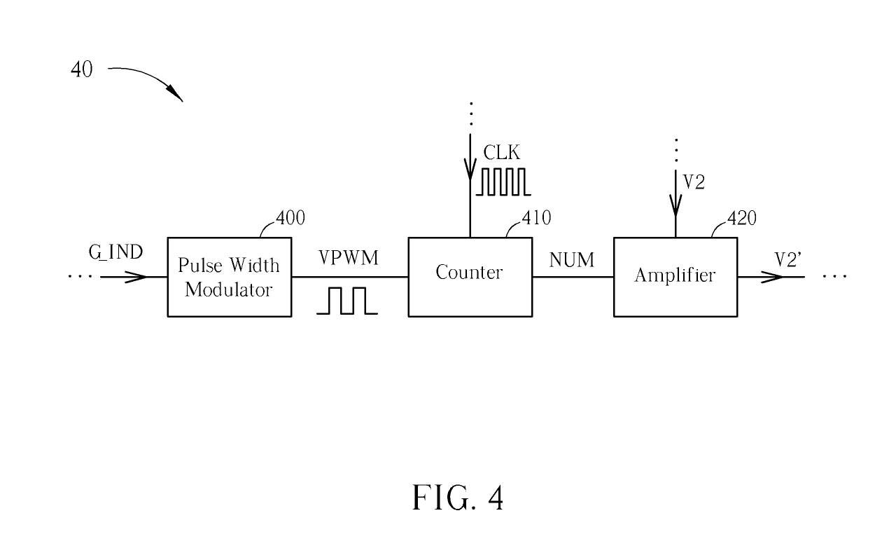

Please refer to FIG. 4, which is a schematic diagram of a signal amplification device 40 according to an embodiment of the present invention. The signal amplification device 40 is utilized for amplifying a signal V2 according to a gain indication signal G_IND. The signal amplification device 40 includes a pulse width modulator 400, a counter 410 and an amplifier 420. The pulse width modulator 400 is utilized for generating a pulse width modulation (PWM) signal VPWM according to the gain indication signal G_IND. The counter 410 is utilized for counting a width cycle number NUM of the PWM signal VPWM according to a standard clock signal CLK. Finally, the amplifier amplifies the signal V2 according to the cycle number NUM to generate an amplified signal V2′.

In short, to overcome the problems of erroneous conversion, unstable gain and extra layout area due to additional bits of the digital signal DGT, the counter 410 replaces the lowpass filter 102 and the ADC 104. That is, instead of acquiring a mean value of the PWM signal VPWM, the present invention directly measures width of an excited state of the PWM signal VPWM per cycle. Since circuit layout area of the counter 410 is smaller than circuit layout area of the lowpass filter 102 and the ADC 104, the signal amplification device 40 can be implemented at a lower cost. In addition, the counter 410 is a digital logic circuit, and therefore is more robust against variations of the power voltage and the ground voltage than the ADC 104. In such a situation, the signal amplification device 420 can economically amplify the signal V2 with a fixed gain.

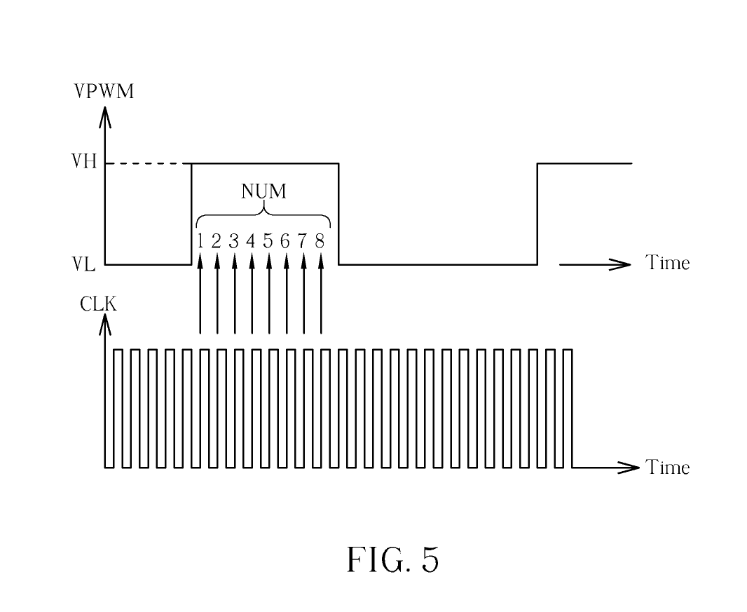

In detail, please refer to FIG. 5, which is a timing diagram of the PWM signal VPWM and the standard clock signal CLK processed in the counter 410. Preferably, a duty cycle of the PWM signal VPWM is directly proportional to the gain indicated by the gain indication signal G_IND. In such a situation, the counter 410 preferably detects the PWM signal VPWM at rising edges of the standard clock signal CLK. If the PWM signal VPWM is at a high potential VH (excited state), the counter 410 accumulates the width cycle number NUM. On the contrary, if the PWM signal VPWM is at a low potential VL, the counter 410 zeros the width cycle number NUM. As a result, the accumulated width cycle number NUM prior to zero is directly proportional to the gain, and is indicative of an amplification rate for the signal V2 in the amplifier 420. Since cycle of the standard clock signal CLK is employed as a unit for width measurement of the PWM signal VPWM, the PWM signal VPWM is measurable only if the PWM signal VPWM is slower than the standard clock signal CLK in frequency.

For example, if the gain has 100 stages and the frequency of the PWM signal VPWM is 1 kHz, the standard clock signal CLK is preferably 100 kHz. In such a situation, the counter 410 generates the width cycle number NUM ranging from 0 to 99 respectively corresponding to the 100 gain stages. In comparison, the ADC 104 employed in the signal amplification device 10 of the prior art has to generate the digital signal DGT with seven bits to represent the 100 gain stages. Since a 7-bit ADC requires more layout area and higher circuit accuracy than a 7-bit counter, the signal amplification device 40 replacing the ADC 104 by the counter 410 costs less, and is more robust than the signal amplification device 10.

Note that, number of gain stages should be taken into consideration when the frequencies of the PWM signal VPWM and the standard clock signal CLK are designed, such that the cycle of the standard clock signal CLK can be utilized as a unit for measuring the PWM signal VPWM. That is, when the duty cycle of the PWM signal VPWM is 100%, the width cycle number NUM corresponds to the highest gain stage. Inversely, when the duty cycle of the PWM signal VPWM is 0%, the width cycle number NUM corresponds to the lowest gain stage.

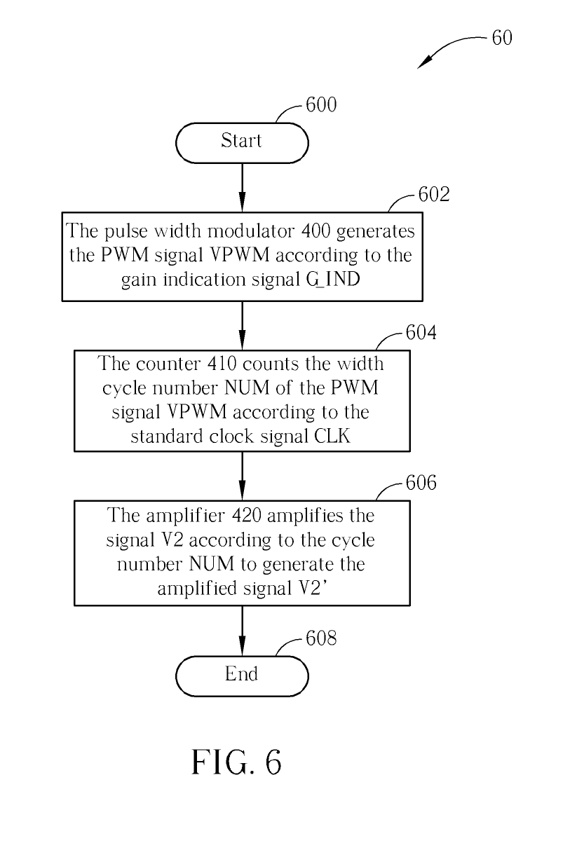

Operations of the signal amplification device 40 can be summarized into a signal amplification process 60, as illustrated in FIG. 6. The signal amplification process 60 includes the following steps:

Step 600: Start.

Step 602: The pulse width modulator 400 generates the PWM signal VPWM according to the gain indication signal G_IND.

Step 604: The counter 410 counts the width cycle number NUM of the PWM signal VPWM according to the standard clock signal CLK.

Step 606: The amplifier 420 amplifies the signal V2 according to the cycle number NUM to generate the amplified signal V2′.

Step 608: End.

Details of the signal amplification process 60 can be referred in the above, and are not narrated herein.

In the prior art, with the increase of the bit number N of the digital signal DGT outputted by the ADC 104, tolerance range for correct conversion shrinks, resulting in the converted digital signal DGT varying between adjacent stages. Such an erroneous digital signal DGT is indicative of an unstable gain of the amplifier 106, which is disadvantageous for circuit application. In comparison, the present invention replaces the lowpass filter 102 and the ADC 104 by the counter 104 to estimate the gain through measuring the PWM signal VPWM. Since the counter 410 is a digital logic circuit, the counter 410 is more robust against noise and requires less circuit layout area than the ADC 104. As a result, the signal amplification device 40 can economically amplify the signal V2 with a fixed gain.

To sum up, the present invention estimates the gain applied to the amplifier through measuring width of the PWM signal to increase error tolerance range and reduce the manufacturing cost.

Those skilled in the art will readily observe that numerous modifications and alterations of the device and method may be made while retaining the teachings of the invention.

What is claimed is:

1. A signal amplification device for amplifying a signal according to a gain indication signal, the signal amplification device comprising:
a pulse width modulator, for generating a pulse width modulation (PWM) signal according to the gain indication signal;
a counter, for counting a width cycle number of the PWM signal according to a standard clock signal; and
an amplifier, for amplifying the signal according to the cycle number to generate an amplified signal.

2. The signal amplification device of claim 1, wherein a frequency of the PWM signal is lower than a frequency of the standard clock signal.

3. The signal amplification device of claim 2, wherein the counter counts a cycle number of an excited state of the PWM signal per cycle using a period of the standard clock signal as a unit to calculate the width cycle number.

4. The signal amplification device of claim 1, wherein a duty cycle of the PWM signal is directly proportional to a gain indicated by the gain indication signal.

5. A signal amplification method for amplifying a signal according to a gain indication signal, the signal amplification method comprising:
generating a pulse width modulation (PWM) signal according to the gain indication signal;
counting a width cycle number of the PWM signal according to a standard clock signal; and
amplifying the signal according to the cycle number to generate an amplified signal.

6. The signal amplification method of claim 5, wherein a frequency of the PWM signal is lower than a frequency of the standard clock signal.

7. The signal amplification method of claim 6, wherein the step of counting the width cycle number of the PWM signal according to the standard clock signal comprises counting a cycle number of an excited state of the PWM signal per cycle using a period of the standard clock signal as a unit to calculate the width cycle number.

8. The signal amplification method of claim 5, wherein a duty cycle of the PWM signal is directly proportional to a gain indicated by the gain indication signal.
